(19) United States
(12) Patent Application Publication
(10) Pub. No.: US 2011/0272022 A1
(43) Pub. Date: Nov. 10, 2011

(54) ELECTRODE FOR A SOLAR CELL, MANUFACTURING METHOD THEREOF, AND SOLAR CELL

(76) Inventors: Cheol Ho Dan, (US); Tae Hyun Jun, (US); Ha Chul Song, (US)

(21) Appl. No.: 13/162,642

(22) Filed: Jun. 17, 2011

Related U.S. Application Data
(63) Continuation of application No. PCT/KR2009/007555, filed on Dec. 17, 2008.

(30) Foreign Application Priority Data
Dec. 17, 2008 (KR) 10-2008-0128511

(51) Int. Cl. H01L 31/0224; H01L 31/18

(52) U.S. Cl. 136/256; 427/74

(57) ABSTRACT

There is provided an electrode for a solar cell, in which the electrode is printed using a polymer binder with a low Tg (hereinafter, referred to as a low Tg polymer binder) to improve a contact property between a substrate such as silicon wafer, or the like, and a conductive electrode material, and subsequently, using a polymer binder with a high Tg (hereinafter, referred to as a high Tg polymer binder) to improve the aspect ratio. The printed electrode is fired, thereby obtaining the electrode with a high aspect ratio, an improved contact property between the substrate and the conductive electrode material, and an enhanced cell efficiency. There is also provided a manufacturing method thereof and a solar cell.

### CROSS REFERENCE TO RELATED APPLICATION(S)

This application is a continuation of International Patent Application No. PCT/KR2009007555, filed on Dec. 17, 2009, which claims the benefit of Korean Patent Application No. 10-2008-0128511 filed on Dec. 17, 2008, the entire disclosures of which are incorporated herein by reference for all purposes.

### BACKGROUND

1. Field

The following description relates to an electrode for a solar cell, a method for manufacturing the same, and a solar cell.

2. Description of Related Art

A solar cell is a semiconductor device for converting solar energy to an electric energy. The solar cell may have a p-n junction, and the fundamental structure thereof is the same as a diode. When a light is incident into the solar cell, the incident light is absorbed to the solar cell and is interacted with a material constituting the semiconductor of the solar cell. As a result, electrons and holes as minority carriers are formed, and they drift to connected electrodes of both sides before a recombination, thereby obtaining electromotive force.

Generally, crystalline silicon solar cells are classified into a single crystal type and a polycrystalline type. A material of the single crystal type has a high efficiency with high property due to a high purity and a low defect density, but the material of the single crystal type is expensive. Although a material of the polycrystalline type has a slightly low efficiency as compared with the material of the single crystal, it is relatively cheap, and thus it is generally used.

A method for manufacturing the polycrystalline silicon solar cell is as follows. The p type polycrystalline silicon substrate with a certain size (for example the commercialized size of the substrate is about 5″ or 6″) and a thickness (about 150˜250 μm) is etched by a proper etching method in order to eliminate defects of a surface of the polycrystalline silicon substrate to be used. Next, a material including phosphorus or POCl3 is supplied in a gaseous phase or a liquid phase, and the phosphorus is doped with a certain thickness (about 0.1˜0.3 μm) of the surface of the p type substrate by a thermal diffusion.

Then, an n type of emitter is formed. After that, so as to remove the by-product such as vitreous material including phosphorus that is generated during the process, a wet etching process using an acid or a base is included. Also, in order to eliminate the doped phosphorous at the rest portion except for the front portion where the light is incident, a dry etching using plasma is performed. After that, the crystalline or amorphous silicon nitride, silicon oxide, titanium oxide, or the combination thereof is deposited by a physical vapor deposition with a proper thickness (about 70˜90 in the case of the silicon nitride) in order to improve the efficiency of the solar cell.

Subsequently, a p type semiconductor layer electrode and an n type semiconductor layer electrode are printed with predetermined line width and height by a printing method (generally, a screen printing), and are dried. In particular, an electrode on the incident surface where the light is incident generally includes silver, and has a line width of about 100 μm and a height of about 30 μm. The other electrode on the surface opposite to the incident surface is generally formed by screen-printing aluminum or a combination of aluminum and silver with uniform thickness with consideration of bowing of the substrate and drying the same.

After that, the electrodes are fired at the relatively high temperature of about 700 to 900° C. for several seconds to several hundred seconds, and then, the conductive metals of the front and rear electrodes are in contact with each of the semiconductor layer. Accordingly, the front and rear electrodes function as electrodes.

### SUMMARY

In the above general process for manufacturing the solar cell, especially at the printing the front electrodes (bus electrodes and/or finger electrodes), the electrodes with the line width of about 80 μm to about 120 μm are printed by a screen printing. In this case, there are several problems, for example, a quality of the line shape is not good, a working property is poor due to clogging of a printing plate caused by the repeated printings, the multi-layer printing is not easy, and an aspect ratio decreases at firing.

In order to solve the above problems, there is provided a method for manufacturing an electrode for a solar cell. In the method, the electrode is printed to have a plurality of layers by a printing method, such as a gravure offset, using conductive pastes. Each of the conductive pastes for each of the layers has a polymer binder with different glass transition temperature and different boiling temperature. Thus, the electrode can have a high aspect ratio and the contact between a substrate and the conductive electrode material can be excellent. There is also provided a solar cell manufactured by the method and having a high cell efficiency.

In one general aspect, there is provided a method for manufacturing an electrode for a solar cell by a printing method through using a composition for an electrode for a solar cell. The composition includes a polymer binder, a diluting solvent, a metal electrode material, and a glass powder. The method includes printing a composition for an electrode for a solar cell including a low Tg polymer binder as the polymer binder on a substrate to improve a contact property between the substrate and the conductive electrode material; and printing a composition for an electrode for a solar cell including a high Tg polymer binder as the polymer binder to improve an aspect ratio.

The low Tg polymer binder may have a Tg of about −40˜10° C., and the high Tg polymer binder may have a Tg of about 50˜120° C.

The method may further include printing a composition including a middle Tg polymer binder between printing the composition including the low Tg polymer binder and printing the composition including the high Tg polymer binder. The middle Tg polymer binder may have a Tg between the Tg of the low Tg polymer binder and the Tg of the high Tg polymer binder.

Also, in the method, the electrode having a high property may be formed by a gravure offset printing method.

In addition, the aspect ratio (height/width) of the electrode may be about 0.3˜1.0 after the printing the composition including the high Tg polymer binder and firing the same. The electrode manufactured by the above method may have a width of about 30˜100 μm, and a height of about 30˜100 μm.

In another aspect, there is provided a substrate for a solar cell including a bus electrode and a finger electrode on an upper portion of the substrate. At least one of the bus electrode and the finger electrode is formed by firing a lower printing layer printed using a conductive paste composition including a low Tg polymer binder and a upper printing layer printed using a conductive paste composition including a high Tg polymer binder.

The at least one of the bus electrode and the finger electrode may have a width of about 30˜100 μm, a height of about 30˜100 μm, and an aspect ratio (height/width) of about 0.3˜1.0.

In another aspect, there is provided a solar cell including a bus electrode and a finger electrode on an upper portion of a substrate, and a rear electrode on a lower portion of the substrate. At least one of the bus electrode and the finger electrode is manufactured by the above method, and the solar cell has a cell efficiency of about 17% or more.

Other features and aspects may be apparent from the following detailed description, the drawings, and the claims.

### BRIEF DESCRIPTION OF DRAWINGS

FIG. 1 illustrates a schematic view of an electrode manufactured by a method according to one embedment, which uses binders having different Tgs.

FIG. 2 illustrates photographs of an electrode in Embodiment 1, and Comparative Examples 1 to 3, in which the electrode is formed by stacking the electrode composition and heat-treating the same at 800° C. for 20 seconds.

FIG. 3 illustrates a photograph for evaluating contact property between the silicon wafer and the electrode in Embodiment 1 and Comparative Example 1.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DESCRIPTION

The following detailed description is provided to assist the reader in gaining a comprehensive understanding of the methods, apparatuses, and/or systems described herein. Accordingly, various changes, modifications, and equivalents of the methods, apparatuses, and/or systems described herein will be suggested to those of ordinary skill in the art. Also, descriptions of well-known functions and constructions may be omitted for increased clarity and conciseness.

In a solar cell and a method for manufacturing an electrode for the solar cell, the electrode is printed using a polymer binder with a low Tg (hereinafter, referred to as a low Tg polymer binder) to improve a contact property between a substrate such as silicon wafer or the like and a conductive electrode material. Subsequently, the electrode is printed using a polymer binder with a high Tg (hereinafter, referred to as a high Tg polymer binder) to improve the aspect ratio. Next, the printed electrode is fired. According to the method, the electrode can have a high aspect ratio, an improved contact property between the substrate and the conductive electrode material, and an enhanced cell efficiency.

Hereinafter, with reference to drawings and embodiments, various aspects are further described. The following descriptions relate to examples. Thus, even though there are conclusive and/or limitative terms or expressions, they do not limit the scope of the following description that is determined by claims.

In various aspects, there is provided a method for manufacturing an electrode for a solar cell by a printing method through using a composition for an electrode for a solar cell. The composition includes a polymer binder, a diluting solvent, a metal electrode material, and a glass powder. The method includes printing a composition for an electrode for a solar cell including a low Tg polymer binder as the polymer binder on a substrate to improve contact between the substrate and the conductive electrode material, and printing a composition for an electrode for a solar cell including a high Tg polymer binder as the polymer binder to improve an aspect ratio.

### DESCRIPTIONS REGARDING MAIN REFERENCE SIGNS IN DRAWINGS

10: substrate.

20: lower printing layer formed by an electrode paste including low Tg polymer binder.

30: high printing layer formed by an electrode paste including high Tg polymer binder.

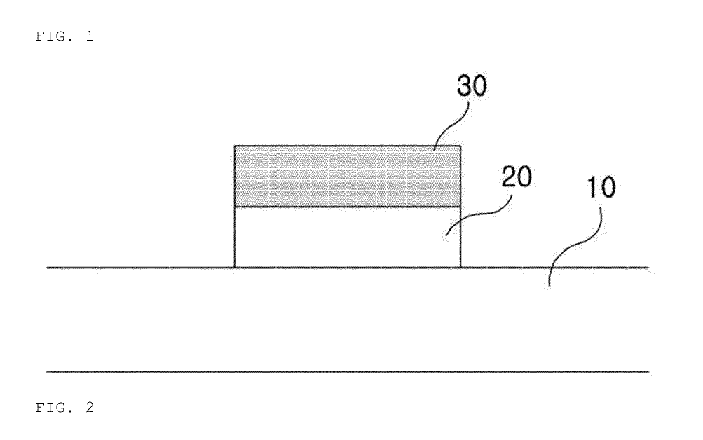

FIG. 1 illustrates a schematic view of an electrode manufactured by a method according to one embodiment, which uses binders having different Tgs. The electrode includes a lower printing layer 20 formed on a substrate 10 by printing a conductive paste composition including a low Tg polymer binder, and a high printing layer 30 formed on the lower printing layer 20 by printing a conductive paste composition including a high Tg polymer binder.

Various conductive paste compositions can be applied to the electrode for the solar cell and can form the electrode shape by a printing method may be used for the conductive paste compositions. For example, the conductive paste may include a polymer binder, a diluting solvent, a metal electrode material, a glass powder, and an inorganic thixotropic agent.

The kind of the binder has an effect on properties of the electrode and on efficiency of the solar cell.

Generally, when firing is performed after printing of the electrode, due to a rheology property of the conductive paste with a low viscosity and a flowability caused by weight of the conductive paste, it is difficult for the electrode to have a height higher than a certain height. In the present embodiment, glass transition temperature of the binder among the conductive paste materials is adjusted. When the high Tg polymer binder with the Tg of about 50° C. or more (preferably about 100° C. or more) is used, an aspect ratio after the firing is similar to an aspect ratio before the firing, contrary to the conventional conductive paste. However, when the pastes having the binders with the same Tg are printed and stacked, the contact property between the substrate (such as, the Si wafer) and the electrode may be low, and thus the efficiency may decrease.

In the present embodiment, the electrode is formed by a gravure offset method, and each of the conductive pastes for each of the layers has a polymer binder with different glass transition temperature. Thereby, the aspect ratio variation before and after firing can be prevented, and the contact property between the substrate and the electrode can increase. Accordingly, a surface where sunlight is incident increases, and thus, the efficiency can be improved. That is, by controlling the glass transition temperature of binder in the layers, the aspect ratio before and after the firing does not change, contrary to the conventional conductive paste. Thus, the surface where the sunlight is incident increases, and thus, the efficiency can be improved.

For example, in the present embodiment, the composition including the low Tg polymer is firstly printed to improve a contact property between the substrate and the electrode. Subsequently, the composition including the high Tg polymer is printed to improve an aspect ratio. The low Tg polymer binder and the high Tg polymer binder may be relatively defined by a value of the Tg. The low Tg polymer binder may have the Tg of about −40˜10° C., and the high Tg polymer binder has the Tg of about 50˜120° C. Also, the composition including a middle Tg polymer binder may be printed between the printing the composition including the low Tg polymer binder and the printing the composition including the high Tg polymer binder. The middle Tg polymer binder may have a Tg between the Tg of the low Tg polymer binder and the Tg of the high Tg polymer binder.

The polymer binder used for the conductive paste composition is not limited thereto. For example, the polymer binder may include at least one of a cellulose ester based compound, a cellulose ether based compound, an acryl based compound, and a vinyl based compound. The cellulose ester based compound may include cellulose acetate, and cellulose acetate butyrate. The cellulose ether based compound may include ethyl cellulose, methyl cellulose, hydroxypropyl cellulose, hydroxyethyl cellulose, hydroxylpropylmethyl cellulose, and hydroxylpropylethyl cellulose. The acryl based compound may include poly acrylamide, poly methacrylate, poly methyl methacrylate, and poly ethyl methacrylate. The vinyl based compound may include poly vinyl butyral, poly vinyl acetate, and poly vinyl alcohol. The acryl based compound may have a molecular weight of about 5,000˜50,000.

The low Tg polymer binder may include at least one of ethyl acrylate (EA), hydroxy ethyl acrylate(HEA), hydroxy propyl acrylate(HPA), 2-ethyl hexyl acrylate(2-EHA), butyl acrylate(BA), stearyl methacrylate(SMA), vinyl butyl ether(VBE), vinyl ethyl ether (VEE), vinyl isobutyl ether (VIE), and vinyl methyl ether (VME). The high Tg polymer binder may include at least one of acryl binders and a cellulose derivates. The acryl binders may include at least one of acrylic acid (AA), methyl acrylic acid (MAA), methyl methacrylate (MMA), ethyl methyl acrylate (EMA), isobutyl methacrylate (i-BMA), 2-hydroxy ethyl methyl acrylate (2-HEMA), styrene monomer (SM), glycidyl methacrylate (GMA), acryl amide(AAM), acrylo nitrile (AN), methacrylo nitrile (MAN). The cellulose derivates may include ethyl cellulose, hydroxyethyl cellulose, hydroxypropyl cellulose, and hydroxyethylhydroxypropyl cellulose.

The diluting solvent may include at least one of alpha-terpineol, texanol, dioctyl phthalate, dibutyl phthalate, cyclohexane, hexane, toluene, benzyl alcohol, dioxane, diethylene glycol, ethylene glycol mono butyl ether, ethylene glycol mono butyl ether acetate, diethylene glycol mono butyl ether, and diethylene glycol mono butyl ether acetate.

The conductive metal material used at the paste composition may be a silver powder, a cupper powder, a nickel powder, or an aluminum powder. For convenience, the conductive metal material of the silver powder is described as an embodiment.

The silver powder may have an average particle size of about 0.5˜5 μmm, and have at least one of a sphere shape, a needle shape, a plate shape, and an amorphous shape. The average particle size may be about 0.5˜5 μmm to have a high density at the firing and to easily form the paste. The silver powder may be included in an amount of about 60˜90 wt % based on the total weight of the conductive paste composition, considering a thickness and a line resistance of the electrode formed at the printing.

The glass frit may have an average particle size of about 0.5˜5 μm. The glass frit may be at least one glass frit having about 43˜91 wt % of PbO, about 21 wt % or less of SiO₂, about 25 wt % or less of B₂O₃+Bi₂O₃, about 7 wt % or less of Al₂O₃, about 20 wt % or less of ZnO, about 15 wt % or less of Na₂O+K₂O+Li₂O, and about 15 wt % or less of BaO+CaO+MgO+SrO. The glass frit may have a glass softening temperature of about 320˜520° C., and may have a thermal expansion coefficient of about 62×10⁻⁷/° C. to about 110×10⁻⁷/° C. The glass frit may be included in an amount of about 1˜10 wt % based on the total weight of the conductive paste composition. When the amount is below 1 wt %, the incomplete firing may be induced and the resistivity may be high. When the amount is above 10 wt %, the amount of the glass component in the fired body of the silver powder may be large and the specific resistivity may be high.

Also, additives conventionally used (for example, a dispersing agent, a deformer agent, or a leveling agent) may be added to the composition.

The conductive paste composition according to the present embodiment may be useful to manufacturing an electrode for a solar cell.

The method for manufacturing the electrode using the conductive paste composition includes a step of directly printing conductive paste compositions including binders having different Tg to have a plurality of layers on a substrate, a step of drying the printed electrode paste, and a step of firing the printed electrode paste.

The conductive paste composition may be printed by several printing methods, for example, a screen printing method, a gravure offset printing method, a rotary screen printing method, a lift-off method, and so on. The gravure offset printing method may be used because it is suitable to form a fine pattern. The electrode may have a thickness of about 10˜40 μm.

The electrode paste formed and patterned using the conductive paste composition may be dried at a temperature of about 250° C. for several minutes, and may be fired at a temperature of about 700˜900° C. for several seconds.

The step of printing and patterning the conductive paste compositions including binders having different Tgs to have a plurality of layers is further described.

The conductive paste composition may be for a front electrode of a solar cell, which is fired at about 700˜900° C. The paste may include about 49˜85 wt % of the metal powder, about 1˜10 wt % of the glass powder, and about 7˜50 wt % of the organic material. The silver powder may be used for the metal powder. The silver powder may have an average particle size of about 0.5˜5 μm and include at least one of a sphere shape, a needle shape, a plate shape, and an amorphous shape. The glass frit may have an average particle size of about 0.5˜5 μm. The glass frit may be at least one glass frit having about 21 wt % or less of SiO₂, about 25 wt % or less of B₂O₃+Bi₂O₃, about 7 wt % or less of Al₂O₃, about 20 wt % or less of ZnO, about 15 wt % or less of Na₂O+K₂O+Li₂O, and about 15 wt % or less of BaO+CaO+MgO+SrO. The glass frit may have a glass softening temperature of about 320˜520° C., and may have a thermal expansion coefficient of about 62×10⁻⁷/° C. to about 110×10⁻⁷/° C. About 7˜50 wt % of the organic material may include about 4˜20 wt % of the polymer binder, about 4˜20 wt % of the diluting solvent, and about 2˜5 wt % of the additives.

First, the paste may include about 49˜85 wt % of the metal powder as a main material for electric conductivity, about 1˜10 wt % of the glass powder for promoting the sintering and increasing adhesion at the interface between the silicon wafer substrate and the electrode, and about 7˜50 wt % of the organic material for combining the powders. A part of the organic material may be replaced with about 2˜5 wt % of additives such as a rheology-controlling agent and dispersing agent, and a leveling agent.

When the silver powder is used for the metal powder, the silver powder may have an average particle size of about 0.5˜15 μm and have a sphere shape, a needle shape, a plate shape, and an amorphous shape. When the average particle size is below about 0.5 μm, it may be difficult to form the paste. When the average particle size is above about 15 μm, the electrode may not be sufficiently densified at the firing and the pore may be generated. Thus, specific resistivity may be high. When the amount of the silver powder is below about 49 wt %, the resistivity of the electrode for the solar cell may be high. When the amount of the silver powder is above about 85 wt %, it may be difficult to be printed by a generally used method since the viscosity of the paste composition is high.

The glass frit may be included in an amount of about 1˜10 wt % based on the total weight of the conductive paste composition. The glass frit may be at least one glass frit having about 21 wt % or less of SiO₂, about 25 wt % or less of B₂O₃+Bi₂O₃, about 7 wt % or less of Al₂O₃, about 20 wt % or less of ZnO, about 15 wt % or less of Na₂O+K₂O+Li₂O, about 15 wt % or less of BaO+CaO+MgO+SrO. The glass frit may have a glass softening temperature of about 320˜520° C., and may have a thermal expansion coefficient of about 62×10⁻⁷/° C. to about 110×10⁻⁷/° C.

When the amount of SiO₂ is above about 21 wt %, the glass softening temperature may increase and the sintered degree may decreases. When the amount of B₂O₃+Bi₂O₃ is above about 25 wt %, the glass softening temperature may increase and the flowability may be low. When the amount of the Al₂O₃ is above about 7 wt %, the glass softening temperature may increase. When the amount of the ZnO is above 35 wt %, the viscosity change at a high temperature may be slow. When the amount of the Na₂O+K₂O+Li₂O is above about 15 wt %, the crystalline property may be low. When the amount of the BaO+CaO+MgO+SrO is above about 15 wt %, the glass softening temperature may increase and the flowability may be low. When the amount of the glass frit is below 1 wt %, the incomplete firing may be induced and the resistivity may be high. When the amount of the glass frit is above 10 wt %, the amount of the glass component in the fired body of the silver powder may be large and the resistivity may be high. The glass frit may have the glass softening temperature of about 320˜520° C., and may have the thermal expansion coefficient of about 62×10⁻⁷/° C. to about 110×10⁻⁷/° C. When the glass softening temperature is above about 520° C., the flowability may be low and the sintered degree may decrease. When the glass softening temperature is below about 320° C., the flowability may be too high, and thus, the sintered degree may decrease. When the thermal expansion coefficient is below about 62×10⁻⁷/° C., the electrode may be cut off at the firing. When the thermal expansion coefficient is above about 110×10⁻⁷/° C., the straightness of the electrode may be low.

About 7˜50 wt % of the organic material may include about 4˜20 wt % of the polymer binder, about 4˜20 wt % of the diluting solvent, and about 2˜5 wt % of the additives. The binder may be at least one of a cellulose acetate based compound, a cellulose ether based compound, an acryl based compound, and a vinyl based compound. The cellulose acetate based compound may include cellulose acetate, and cellulose acetate butyrate. The cellulose ether based compound may include ethyl cellulose, methyl cellulose, hydroxypropyl cellulose, hydroxyethyl cellulose, hydroxypropylmethyl cellulose and hydroxylpropylethyl cellulose. The acryl based compound may include poly acrylamide, poly methacrylate, poly methyl methacrylate, and poly ethyl methacrylate. The vinyl based compound may include poly vinyl butyral, poly vinyl acetate, and poly vinyl alcohol. When the amount of the binder is above about 20 wt %, a ratio of an electrode height to an electrode width (an average of minimum widths and maximum width of the electrodes after firing the printed paste, hereinafter referred to as “electrode width”) by one-time printing may be low (about 4% or less). Thus, in order to obtain the line resistance that is less than a predetermined value, a number of printing may increase. When the amount of the binder is below about 4 wt %, the binder may not perform an original function for maintaining a shape of the electrode at the firing.

The binder is a factor for controlling viscosity of the paste. The paste may have a viscosity of about 5,000˜300,000 cps. The viscosity has an effect on the sintering spread ratio (a ratio a maximum width of an electrode after printing and firing the conductive paste composition with respect to a maximum width of an electrode pattern of a screen mask). When the viscosity is below about 5,000 cps, the sintering spread ratio may be high (about 105% or more). When the viscosity is above about 300,000 cps, productivity of the printing may be low and the electrode may be frequently cut off.

The diluting solvent may include at least one of terpineol, cyclohexane, hexane, toluene, benzyl alcohol, dioxane, diethylene glycol, and so on. When the amount of the diluting solvent is above about 25 wt %, the paste may have the too low viscosity and may be difficult to be printed by the generally used method. Although the printing is possible, the electrode may be largely shrunk at the firing, and thus, may be not used as an electrode. When the amount of the diluting solvent is below about 1 wt %, it is difficult for the paste to penetrate through the screen mask, and the printed electrode may be uneven. Thus, the electrode may have a high line resistance, although the electrode has a sufficient size.

The electrode pattern is formed by the above paste. The viscosity that is the most important property may be 5,000˜300,000 cps (measuring conditions: TT35 Plate by HAAKE, 25° C., 50 rpm). When the viscosity is below about 5,000 cps, the electrode may have a width larger than the designed width. When the viscosity is above about 300,000, productivity of the printing may be low and the electrode may be frequently cut off. A thixotropic index (TI=viscosity at 5 rpm/viscosity at 50 rpm) of the paste has a great effect on a shape maintenance of the electrode. Thus, the thixotropic index may be about 1.5˜5.5.

The solar cell manufactured by the above method may include an additional element to improve its function. For example, in order to reliability of the solar cell, a welding layer may be formed on the electrode.

A substrate for a solar cell manufactured by the above method includes a bus electrode and a finger electrode on an upper portion of the substrate. At least one of the bus electrode and the finger electrode is formed by firing a lower printing layer printed using a conductive paste composition including a low Tg polymer binder and a upper printing layer printed using a conductive paste composition including a high Tg polymer binder. The electrode may have a width of about 30˜100 μm, a height of about 30˜100 μm, and the aspect ratio (height/width) of about 0.3˜1.0.

According to the electrode manufactured by the conductive paste in the present embodiment, since the electrode can have the aspect ratio (height/width) of about 0.3˜1.0, an area where the sunlight is incident can increase (about 93% or more) when it is applied for the solar cell. Also, according to the conductive paste, the line resistance decreases after the firing. Accordingly, the electromotive force generated from the sunlight can be effectively used. Thus, the solar cell can have a cell efficiency of about 17% or more.

### MANUFACTURING EXAMPLE 1

100 g of butyl carbitol acetate (BCA) was put in a 2 L plask, and was stirred at 100° C. A solution including 45.5 g of methyl methacrylate (MMA), 8.5 g of styrene monomer (SM), 30 g of hydroxy ethyl methacrylate (HEMA), 11 g of methyl acrylic acid (MAA), and 5 g of benzyl peroxide were dropped to the BCA for 3 hours. After 1 hour, a solution that 0.15 g of benzyl peroxide was dissolved in 20 g of BCA was added. By checking of heat, when the heat was not generated, it was decided as an end of reactions. Thereby, the resin binder 1 (poly(methylmethacylate-methacrylic acid)) with weight-average molecular weight of 5,000 and Tg of 87° C. was manufactured.

15 g of the manufactured binder 1, 1 g of a dispersing agent (BYK110 made by BYK chemi), and 5 g of frit (average particle size of 1 μm) were dispersed using a 3-roll mill. 38 g of a silver powder (a sphere shape, average particle size of 1 μm) and 40 g of a silver powder (a flake shape, average particle size of 3 μm) were mixed and dispersed using the 3-roll mill. Then, a defoaming process was performed at the reduced pressure. Thereby, the conductive paste was manufactured.

### MANUFACTURING EXAMPLE 2

100 g of butyl carbitol acetate (BCA) was put in a 2 L plask, and was stirred at 100° C. A solution including 21.5 g of methyl methacrylate (MMA), 30 g of butyl acrylic monomer (BAM), 8.5 g of styrene monomer (SM), 20 g of hydroxy ethyl methacrylate (HEMA), 15 g of methyl acrylic acid (MAA), and 5 g of benzyl peroxide were dropped to the BCA for 3 hours. After 1 hour, a solution that 0.15 g of benzyl peroxide was dissolved in 20 g of BCA was added. By checking of heat, when the heat was not generated, it was decided as an end of reactions. Thereby, the resin binder 2 (poly(methylmethacylate-methacrylic acid)) with weight-average molecular weight of 5,000 and Tg of 26° C. was manufactured.

15 g of the manufactured binder 2, 1 g of a dispersing agent (BYK110 made by BYK chemi), and 5 g of frit (average particle size of 1 μm) were dispersed using a 3-roll mill. 38 g of a silver powder (a sphere shape, average particle size of 1 μm) and 40 g of a silver powder (a flake shape, average particle size of 3 μm) were mixed and dispersed using the 3-roll mill. Then, a defoaming process was performed at the reduced pressure. Thereby, the conductive paste was manufactured.

### MANUFACTURING EXAMPLE 3

100 g of butyl carbitol acetate (BCA) was put in a 2 L plask, and was stirred at 100° C. A solution including 5 g of methyl methacrylate (MMA), 57 g of butyl acrylic monomer (BAM), 6 g of styrene monomer (SM), 15 g of hydroxy ethyl methacrylate (HEMA), 7 g of methyl acrylic acid (MAA), and 10 g of benzyl peroxide were dropped to the BCA for 3 hours. After 1 hour, a solution that 0.15 g of benzyl peroxide was dissolved in 20 g of BCA was added. By checking of heat, when the heat was not generated, it was decided as an end of reactions. Thereby, the resin binder 3 (poly(methylmethacylate-methacrylic acid)) with weight-average molecular weight of 5,000 and Tg of −19° C. was manufactured.

15 g of the manufactured binder 3, 1 g of a dispersing agent (BYK110 made by BYK chemi), and 5 g of frit (average particle size of 1 μm) were dispersed using a 3-roll mill. 38 g of a silver powder (a sphere shape, average particle size of 1 μm) and 40 g of a silver powder (a flake shape, average particle size of 3 μm) were mixed and dispersed using the 3-roll mill. Then, a defoaming process was performed at the reduced pressure. Thereby, the conductive paste was manufactured.

The compositions of the conductive pastes are shown in following Table 1.

TABLE 1

| | Manufacturing | Manufacturing | Manufacturing |
|---|---|---|---|
| | Example 1 | Example 2 | Example 3 |
| Binder | 15 (Tg 87° C.) | 15 (Tg 26° C.) | 15 (Tg −19° C.) |
| Diluting | 2.0 | 2.0 | 2.0 |
| solvent | | | |
| Slip | 1.0 | 1.0 | 1.0 |
| Agent ( ) | | | |
| Dispersing | 1.0 | 1.0 | 1.0 |
| Agent | | | |
| Silver | 78 | 78 | 78 |
| Powder | | | |
| Glass | 3 | 3 | 3 |
| Powder | | | |
| Total | 100 | 100 | 100 |

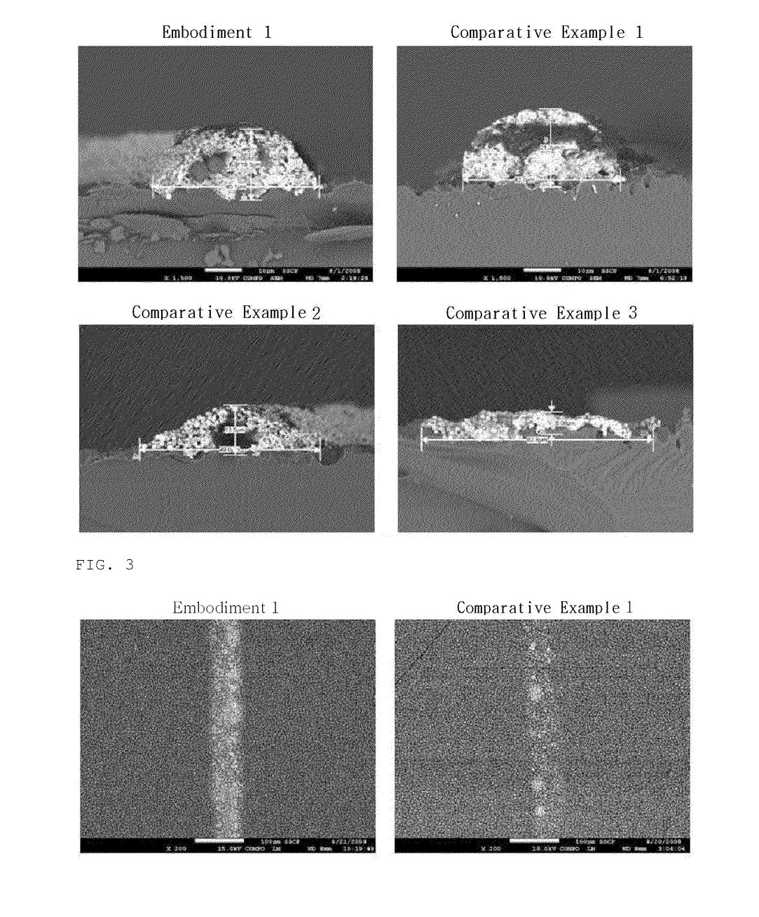

Also, printing methods in Embodiment 1, and Comparative Examples 1 to 3 are shown in following Table 2, and an aspect ratio, a line width, a height, and a cell efficiency of the electrode are shown Table 3, and FIGS. 2 and 3.

TABLE 2

| | | Comparative | Comparative | Comparative |
|---|---|---|---|---|
| | Embodiment 1 | Example 1 | Example 2 | Example3 |
| A number of printing | 3 | 3 | 3 | 3 |
| First layer material | Manufacturing | Manufacturing | Manufacturing | Manufacturing |
| | Example 3 | Example 1 | Example 2 | Example 3 |
| Second layer | Manufacturing | Manufacturing | Manufacturing | Manufacturing |
| material | Example 1 | Example 1 | Example 2 | Example 3 |
| Third layer material | Manufacturing | Manufacturing | Manufacturing | Manufacturing |
| | Example 1 | Example 1 | Example 2 | Example 3 |

TABLE 3

| | Aspect ratio | | Line width | Efficiency |
|---|---|---|---|---|
| | (height/width) | height [μm] | [μm] | (%) |
| Embodiment 1 | 0.428 | 19.3 | 45.1 | 18.9% |
| Comparative | 0.496 | 21.2 | 42.7 | 8.9% |
| Example 1 | | | | |
| Comparative | 0.276 | 13.5 | 49 | 15.8% |
| Example 2 | | | | |
| Comparative | 0.096 | 6.06 | 62.8 | 13.6% |
| Example 3 | | | | |

With reference to Table 3, and FIGS. 2 and 3, when the glass transition temperature is low, the cross section of the electrode collapsed after the firing and the aspect ratio was low (Comparative Example 3). When the glass transition temperature is high, the cell efficiency was low (Comparative Example 1). Contrary to the above, in Embodiment 1 (in which the conductive paste including the low Tg polymer binder was firstly print and the conductive paste including the high Tg polymer binder was secondly printed), the cross section of the electrode did not collapse after the firing, and thus, the aspect ratio was high and the efficiency was enhanced. In addition, the electrode with a sufficient thickness of 10 μm or more and a line width of 10 μm or less can be achieved by the multi-layered printing method.

According to an aspect, a solar cell and a method for manufacturing an electrode for a solar cell, a contact property between a substrate such as a silicon wafer and a conductive electrode material is superior and an aspect ratio is high, thereby improving efficiency. Therefore, it is considerably useful in the art.

Program instructions to perform a method described herein, or one or more operations thereof, may be recorded, stored, or fixed in one or more computer-readable storage media. The program instructions may be implemented by a computer. For example, the computer may cause a processor to execute the program instructions. The media may include, alone or in combination with the program instructions, data files, data structures, and the like. Examples of computer-readable storage media include magnetic media, such as hard disks, floppy disks, and magnetic tape; optical media such as CD ROM disks and DVDs; magneto-optical media, such as optical disks; and hardware devices that are specially configured to store and perform program instructions, such as read-only memory (ROM), random access memory (RAM), flash memory, and the like. Examples of program instructions include machine code, such as produced by a compiler, and files containing higher level code that may be executed by the computer using an interpreter. The program instructions, that is, software, may be distributed over network coupled computer systems so that the software is stored and executed in a distributed fashion. For example, the software and data may be stored by one or more computer readable storage mediums. Also, functional programs, codes, and code segments for accomplishing the example embodiments disclosed herein can be easily construed by programmers skilled in the art to which the embodiments pertain based on and using the flow diagrams and block diagrams of the figures and their corresponding descriptions as provided herein. Also, the described unit to perform an operation or a method may be hardware, software, or some combination of hardware and software. For example, the unit may be a software package running on a computer or the computer on which that software is running.

A number of examples have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

1. A method for manufacturing an electrode for a solar cell by a printing method using a composition comprising a polymer binder, a diluting solvent, a metal electrode material, and a glass powder, the method comprising:
printing a composition for an electrode for a solar cell including a low Tg polymer binder as the polymer binder on a substrate to improve a contact property between the substrate and the conductive electrode material; and
printing a composition for an electrode for a solar cell including a high Tg polymer binder as the polymer binder to improve an aspect ratio.

2. The method of claim 1, wherein the low Tg polymer binder has a Tg of about −40˜10° C.

3. The method of claim 1, wherein the high Tg polymer binder has a Tg of about 50˜120° C.

4. The method of claim 1, wherein the low Tg polymer binder includes at least one of ethyl acrylate (EA), hydroxy ethyl acrylate(HEA), hydroxy propyl acrylate(HPA), 2-ethyl hexyl acrylate(2-EHA), butyl acrylate(BA), stearyl methacrylate(SMA), vinyl butyl ether(VBE), vinyl ethyl ether (VEE), vinyl isobutyl ether (VIE), and vinyl methyl ether (VME).

5. The method of claim 1, wherein the high Tg polymer binder includes at least one of acrylic acid (AA), methyl acrylic acid (MAA), methyl methacrylate (MMA), ethyl methyl acrylate (EMA), isobutyl methacrylate (i-BMA), 2-hydroxy ethyl methyl acrylate (2-HEMA), styrene monomer (SM), glycidyl methacrylate (GMA), acryl amide(AAM), acrylo nitrile (AN), methacrylo nitrile (MAN), ethyl cellulose, hydroxyethyl cellulose, hydroxypropyl cellulose, and hydroxyethylhydroxypropyl cellulose.

6. The method of claim 1, wherein between printing the composition including the low Tg polymer binder and printing the composition including the high Tg polymer binder, the method further comprises:
printing a composition including a middle Tg polymer binder.

7. The method of claim 6, wherein the middle Tg polymer binder has a Tg between the Tg of the low Tg polymer binder and the Tg of the high Tg polymer binder.

8. The method of claim 1, wherein the printing method includes a gravure offset printing.

9. The method of claim 1, wherein the aspect ratio (height/width) of the electrode is about 0.3˜1.0 after printing the composition including the high Tg polymer binder and firing the same.

10. An electrode manufactured by the method of claim 1, wherein the electrode has a width of about 30˜100 μm, a height of about 30˜100 μm, and the aspect ratio (height/width) of about 0.3˜1.0.

11. A substrate for a solar cell comprising:
a bus electrode; and
a finger electrode on an upper portion of the substrate,
wherein at least one of the bus electrode and the finger electrode is formed by firing a lower printing layer printed using a conductive paste composition including a low Tg polymer binder, and an upper printing layer printed using a conductive paste composition including a high Tg polymer binder.

12. The substrate of claim 11, wherein at least one of the bus electrode and the finger electrode has a width of about 30˜100 μm, a height of about 30˜100 μm, and the aspect ratio (height/width) of about 0.3˜1.0.

13. A solar cell including a bus electrode and a finger electrode on an upper portion of a substrate, and a rear electrode on a lower portion of the substrate,
wherein at least one of the bus electrode and the finger electrode is manufactured by the method of claim 1, and
wherein the solar cell has a cell efficiency of about 17% or more.

14. A solar cell including the substrate of claim 13, wherein the solar cell has a cell efficiency of about 17% or more.
